(19) United States
(12) Patent Application Publication
(10) Pub. No.: US 2024/0349458 A1
(43) Pub. Date: Oct. 17, 2024

(54) VARIABLE PIN HEAT SINK

(71) Applicant: GM GLOBAL TECHNOLOGY OPERATIONS LLC, DETROIT, MI (US)

(72) Inventors: Ronald O. Grover, JR., Northville, MI (US); Rajan R. Chakravarty, Troy, MI (US); Jong-Eun Kim, Macomb, MI (US)

(21) Appl. No.: 18/300,541

(22) Filed: Apr. 14, 2023

(51) Int. Cl. H05K 7/20; F28F 3/02

(52) U.S. Cl. CPC H05K 7/20409; F28F 3/022; F28F 2260/00; H01M 10/625; H02K 9/227

(57) ABSTRACT

Aspects of the disclosure include a heat sink having variable pins. An exemplary heat sink can include a plurality of pins extending from a surface of the heat sink. The plurality of pins can include a first pin and a second pin. The first pin can include a first set of pin features and the second pin can include a second set of pin features. The first set of pin features and the second set of pin features differ in at least one pin feature. The heat sink can be configured to remove heat from a component of a vehicle. The component can include an electric motor, a battery pack, and an inverter electrically coupled to the electric motor.

### INTRODUCTION

The subject disclosure relates to heat dissipation technologies, and particularly to a variable pin heat sink.

High voltage electrical systems are increasingly used to power the onboard functions of both mobile and stationary systems. For example, in motor vehicles, the demand to reduce emissions has led to the development of advanced electric vehicles (EVs). EVs rely upon Rechargeable Energy Storage Systems (RESS), which typically include one or more high voltage battery packs, and an electric drivetrain (e.g., an electric motor) to deliver power from the battery to the wheels. The inverter and electric motor in an EV generate a significant amount of heat during operation, especially during periods of high power demand. If this heat is not effectively dissipated, the functionality of various electrical and mechanical components can be affected or have their lifespan reduced and the overall performance of the vehicle can be diminished.

Heat sinks are an excellent source of heat dissipation and are used to dissipate heat generated by various components in an electric vehicle's powertrain, including the inverter, electric motor, and battery. Heat sinks are also a common component in a vehicle's cooling system. Heat sinks are typically used in combination with active and passive cooling systems, such as recirculating liquid and/or air cooling systems. Heat sinks can be designed to absorb heat from a source (e.g., an inverter, charging port terminal, battery pack during charging and/or discharging, etc.) and to transfer that heat to a sink (e.g., a coolant flowing through a cooling system, ambient, etc.). Heat sinks are typically made of materials with high thermal conductivity, such as copper and aluminum, and can include fins or other structures (e.g., heat pipes, thermal grease, etc.) to increase their surface area and maximize heat dissipation. They may also incorporate other features, such as, to further enhance their performance.

### SUMMARY

In one exemplary embodiment a vehicle includes an electric motor configured to drive at least one wheel of the vehicle, a battery pack electrically coupled to the electric motor, and a heat sink thermally coupled to a component of the vehicle. The heat sink can include a plurality of pins extending from a surface of the heat sink. The plurality of pins can include one or more first pins and one or more second pins. The one or more first pins can include a first set of pin features and the one or more second pins can include a second set of pin features. The first set of pin features of the one or more first pins and the second set of pin features of the one or more second pins differ in at least one pin feature. The heat sink can be configured to remove heat from the component of the vehicle. The component can include the electric motor, the battery pack, and an inverter electrically coupled to the electric motor.

In addition to one or more of the features described herein, in some embodiments, each pin feature includes one of a shape, a height, a diameter, a spacing, a degree of taper, a degree of rotation, a surface area, a volume, and a geometry of a respective pin of the plurality of pins.

In some embodiments, the heat sink is thermally coupled to the component (e.g., one of the electric motor, the battery pack, and the inverter electrically coupled to the electric motor).

In some embodiments, the vehicle includes a cooling system having an inlet and an outlet. In some embodiments, the heat sink is positioned on the component and the heat sink and the component are positioned between the inlet and the outlet of the cooling system.

In some embodiments, the heat sink includes a plurality of first pins and a plurality of second pins. In some embodiments, the plurality of first pins and the plurality of second pins are distributed nonuniformly over the surface of the heat sink. In some embodiments, the plurality of first pins are co-located in a first region of the heat sink and the plurality of second pins are co-located in a second region of the heat sink. In some embodiments, at least one of the first region and the second region of the heat sink is discontinuous.

In another exemplary embodiment a heat sink can include a plurality of pins extending from a surface of the heat sink. The plurality of pins can include a first pin and a second pin. The first pin can include a first set of pin features and the second pin can include a second set of pin features. The first set of pin features and the second set of pin features differ in at least one pin feature. The heat sink can be configured to remove heat from a component of a vehicle. The component can include an electric motor, a battery pack, and an inverter electrically coupled to the electric motor.

In yet another exemplary embodiment a method for cooling a component of a vehicle can include thermally coupling a heat sink to the component. The heat sink can include a plurality of pins extending from a surface of the heat sink. The method can include configuring a first pin of the plurality of pins with a first set of pin features and configuring a second pin of the plurality of pins with a second set of pin features. The first set of pin features and the second set of pin features differ in at least one pin feature.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2 is a view of a heat sink in accordance with one or more embodiments;

FIG. 3 illustrates a view of a multi-sided heat sink in accordance with one or more embodiments;

FIG. 4A illustrates a view of a heat sink in accordance with one or more embodiments;

FIG. 4B illustrates a top-down view of the heat sink of FIG. 4A in accordance with one or more embodiments;

FIG. 5A illustrates a view of another heat sink in accordance with one or more embodiments;

FIG. 5B illustrates a top-down view of the heat sink of FIG. 5A in accordance with one or more embodiments;

FIG. 6 illustrates a view of yet another heat sink in accordance with one or more embodiments; and

FIG. 7 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

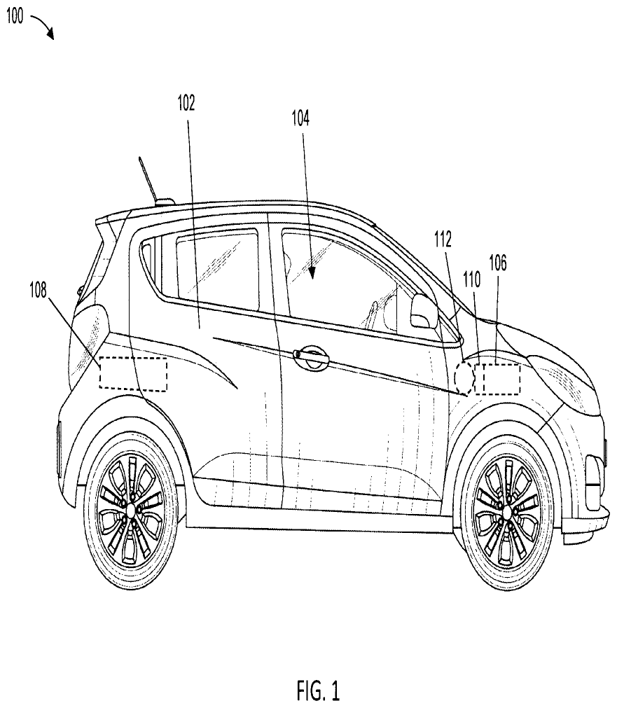

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, an electric motor 106 (shown by projection under the front hood), a battery pack 108 (shown by projection near the rear of the vehicle 100), and an inverter 110 (shown by projection under the front hood). The electric motor 106, battery pack 108, and inverter 110 are shown for ease of illustration and discussion only. It should be understood that the configuration, location, size, arrangement, etc., of the electric motor 106, battery pack 108, and/or inverter 110 is not meant to be particularly limited, and all such configurations (including multi-motor and/or multi-pack configurations) are within the contemplated scope of this disclosure.

As will be detailed herein, heat generated by and for the benefit of various components of the vehicle 100, such as the electric motor 106, the battery pack 108, and the inverter 110 can be dissipated using a heat sink(s) 112. The heat sink 112 is shown for ease of illustration and discussion only. It should be understood that the configuration, location, size, number, arrangement, etc., of heat sinks 112 is not meant to be particularly limited, and all such configurations are within the contemplated scope of this disclosure. Moreover, while the present disclosure is discussed primarily in the context of heat dissipation for an electric vehicle, all aspects of the heat sink 112 described herein can be similarly incorporated within any system (vehicle, building, or otherwise) having a heat generation source (e.g., one or more battery packs, an engine, a cooling system, etc.), and all such configurations and applications are within the contemplated scope of this disclosure.

As discussed previously, heat sinks are an excellent source of heat dissipation and are used to dissipate heat generated by various components in an electric vehicle's powertrain, including the inverter, electric motor, and battery. Unfortunately, many heat sink designs are limited to intuitive design concepts defined by simple, uniform shapes that are uniformly distributed. While somewhat straightforward to manufacture, these types of heat sinks provide a blanket, natively uniform heat dissipation rate and must strike a balance between heat dissipation and pressure drop constraints.

This disclosure introduces a new heat sink architecture that leverages variable pins for nonuniform heat dissipation and pressure drop control. As used herein, a “variable pin” heat sink refers to a heat sink architecture having pins, fins, and/or other extrusions (collectively, “pins”) of varied shape, height, and spacing. In some embodiments, each pin (or subset of pins) can have a unique combination of shape, height, and spacing. In some embodiments, a heat sink is segmented into two or more regions, each region having its own set of unique pin architectures.

Heat sinks constructed with variable pins in accordance with one or more embodiments offer several technical advantages over other heat sink layouts. In short, the heat sinks described herein can optimize the various individual shapes, heights, and spacings of the variable pins to achieve precise, highly localized heat dissipation rates (rather than a global, somewhat uniform heat dissipation rate) while also meeting or exceeding pressure drop constraints. For example, in some embodiments, a heat sink design for an inverter can include variable pins having pin features (shape, height, spacing, etc.) chosen to minimize the maximum chip temperature within pressure drop constraints. Notably, the variable pins can be nonuniformly distributed over the heat sink surface in a manner that can appear randomized (i.e., without a clear or repeating pattern) to a passive observer.

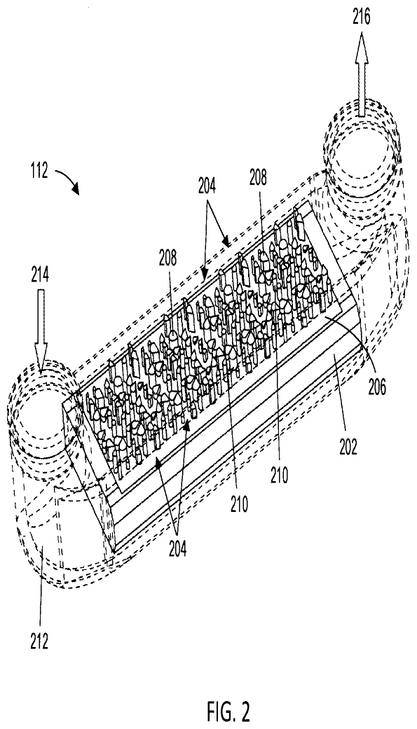

FIG. 2 illustrates a view of a heat sink 112 in accordance with one or more embodiments. The heat sink 112 can be thermally coupled to a component 202. In some embodiments, the component 202 can include, for example, the electric motor 106, the battery pack 108, the inverter 112, etc. of the vehicle 100, although other cooling applications (for vehicles, structures, or otherwise) are within the contemplated scope of this disclosure. The following sections describe the heat sink 112 in the context of the vehicle 100 for ease of discussion and illustration only.

In some embodiments, a plurality of pins, fins, and/or other extrusions (collectively, pins 204) extend from a surface 206 of the heat sink 112. The particular arrangement and configuration of the pins 204 and/or the heat sink 112 shown in FIG. 2 is generally illustrative of a heat sink having variable pins and is not meant to be particularly limited to the exact arrangement and configuration depicted in FIG. 2.

In some embodiments, the pins 204 of the heat sink 112 are variable pins having a unique (strictly or with respect to a subgroup, as desired) selection of pin features. The pin features can include, for example, the shape, size, height, spacing, degree of taper, surface area, volume, geometry, etc., of a respective pin of the pins 204. In some embodiments, the shape of a pin can be, for example, a cylindrical shape, a teardrop shape, and a generalized polyhedral shape (i.e., n-sided shape). In some embodiments, the shape of a respective pin is constant. In some embodiments, the shape of a respective pin evolves from a first shape at a base of the pin (e.g., at the surface of the heat sink 112) to a second shape at a top of the pin (in the direction of extrusion).

In some embodiments, a first pin 208 of the pins 204 has a first set of pin features (as shown, a teardrop style pin of relatively large size). In some embodiments, a second pin 210 of the pins 204 has a second set of pin features (as shown, a cylindrical style pin of relatively small size). Notably, the first pin 208 and the second pin 210 differ in at least one pin feature (here, a teardrop vs. a cylindrical style and a relatively large size vs. a relatively small size). Again, the first pin 208 and the second pin 210 are not meant to be particularly limited, but are merely illustrative of the variable pin concept. In general, each of the pins 204 (e.g., the first pin 208, the second pin 210, etc.) can be constructed to a desired set of pin features, subject to the tooling limits of the associated manufacturing process (e.g., molding, casting, welding, lithography, etc.).

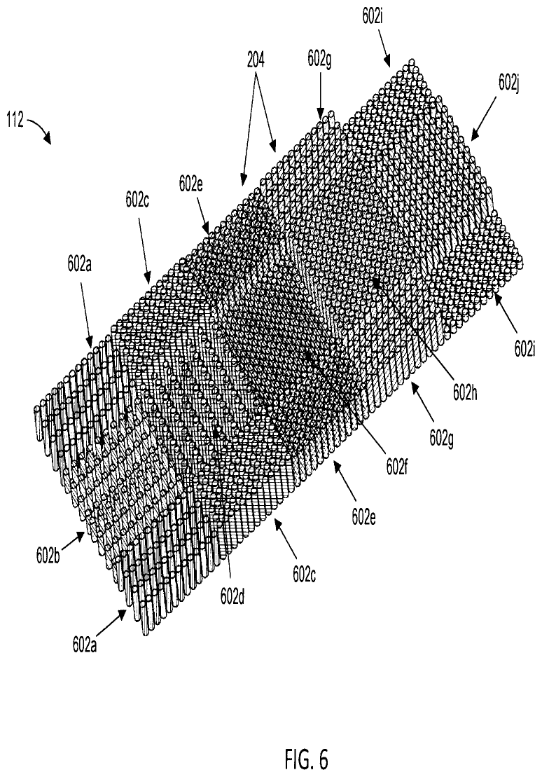

In some embodiments, the heat sink 112 includes a plurality of first pins 208 and/or a plurality of second pins 210. In some embodiments, the plurality of first pins 208 can define a first subset of pins 204 having the first set of pin features and the plurality of second pins 210 can define a second subset of pins 204 having the second set of pin features. In some embodiments, a plurality of pins 204 can be co-located in a shared region(s) of the heat sink 112 (refer to FIG. 6). In some embodiments, a plurality of pins 204 can be distributed throughout the heat sink 112 (as shown in FIG. 2). In other words, the plurality of first pins 208 (or second pins 210, etc.) defining the first (or second, etc.) subset of pins 204 need not be confined to a same region of the heat sink 112.

In some embodiments, the heat sink 112 is coupled to a cooling system 212. In some embodiments, the cooling system 212 is an active and/or passive cooling system, such as, for example, a recirculating coolant and/or air cooling system. In some embodiments, the cooling system 212 is configured to remove heat from the heat sink 112. In some embodiments, the cooling system 212 includes an inlet 214 and an outlet 216. In some embodiments, the cooling system 212 includes a fluid (e.g., a coolant, air, etc., not separately shown) that is configured to flow from the inlet 214, across the heat sink 112, and to the outlet 216. In some embodiments, the cooling system 212 can include a pump (not separately shown) for forcing the fluid across the heat sink 112.

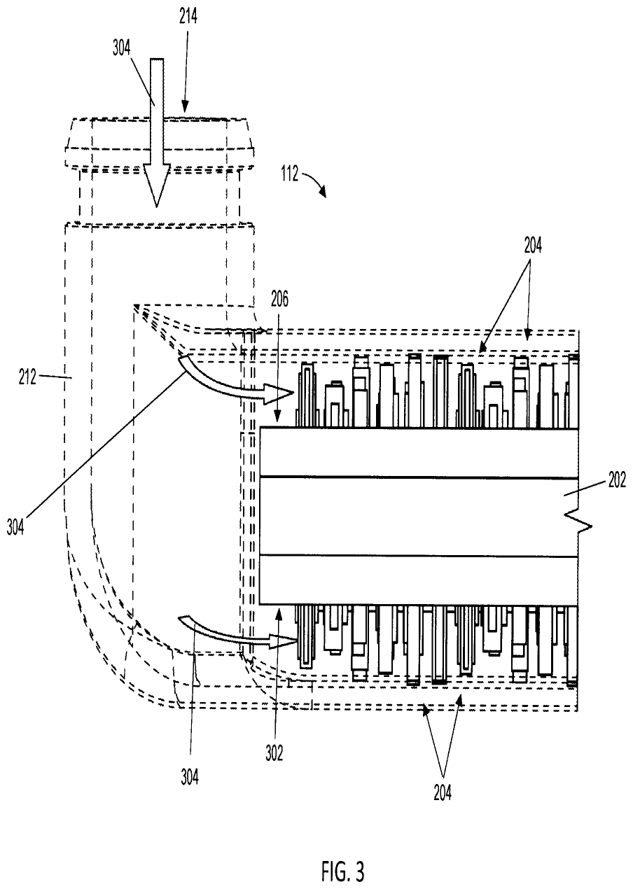

FIG. 3 illustrates a view of a heat sink 112 in accordance with one or more embodiments. The heat sink 112 can be configured in a similar manner as discussed with respect to FIG. 2, except that the heat sink 112 depicted in FIG. 2 is a multi-sided heat sink. In other words, in some embodiments, the pins 204 of the heat sink 112 can extend from the surface 206 (as shown in FIG. 3, the topmost surface of the heat sink 112) as well as from one or more additional surfaces 302 (as shown in FIG. 3, the bottommost surface of the heat sink 112). In some embodiments, the surface 206 and the additional surface 302 are on opposite sides of the component 202. In some embodiments, the additional surfaces 302 include side surfaces (not separately shown) of the heat sink 112. In other words, in some embodiments, the heat sink 112 wraps around an outer perimeter of the component 202 (not separately shown). Advantageously, a multi-sided heat sink such as the one depicted in FIG. 3 can allow for a fluid flow path 304 to pass around the component 202 (i.e., top, bottom, and/or side surfaces of the component 202), improving cooling efficiency.

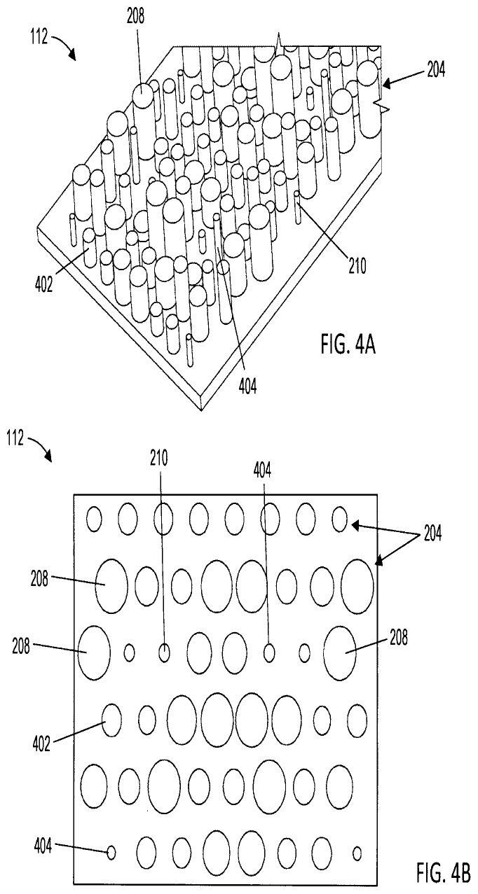

FIG. 4A illustrates a view of a heat sink 112 in accordance with one or more embodiments. As shown in FIG. 4A, the heat sink 112 can include plurality of pins 204. In some embodiments, the pins 204 are variable pins. In some embodiments, the pins 204 share one or more pin features (here, a cylindrical style) but differ in one or more pin features (here, various diameters, heights, and centerline-to-centerline pitch).

In some embodiments, a first pin 208 of the pins 204 has a first set of pin features (as shown, a cylindrical style pin of relatively large diameter and height). In some embodiments, a second pin 210 of the pins 204 has a second set of pin features (as shown, a cylindrical style pin of relatively small diameter and height). In some embodiments, a third pin 402 of the pins 204 has a third set of pin features (as shown, a cylindrical style pin of moderate diameter and height). In some embodiments, a fourth pin 404 of the pins 204 has a fourth set of pin features (as shown, a cylindrical style pin of relatively small diameter but relatively high height). The first pin 208, the second pin 210, the third pin 402, and fourth pin 404 depicted in FIG. 4A are not meant to be particularly limited, but are merely illustrative of the variable pin concept.

FIG. 4B illustrates a top-down view of the heat sink 112 of FIG. 4A in accordance with one or more embodiments. As shown in FIG. 4B, the heat sink 112 can include plurality of pins 204, such as, for example, the first pin 208 having a first set of pin features (as shown, a cylindrical style pin of relatively large diameter), the second pin 210 having a second set of pin features (as shown, a cylindrical style pin of relatively small diameter), the third pin 402 having a third set of pin features (as shown, a cylindrical style pin of moderate diameter), and fourth pin 404 having a fourth set of pin features (as shown, a cylindrical style pin of relatively small diameter).

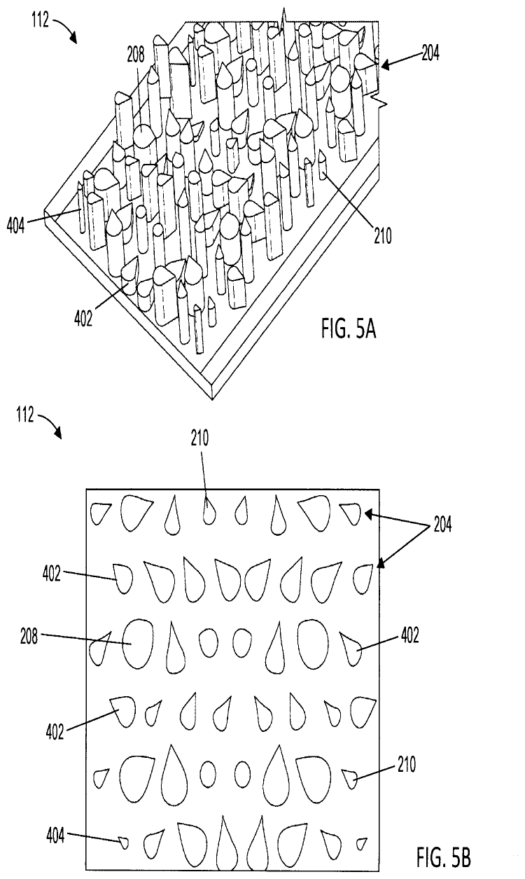

FIG. 5A illustrates a view of a heat sink 112 in accordance with one or more embodiments. As shown in FIG. 5A, the heat sink 112 can include plurality of pins 204. In some embodiments, the pins 204 are variable pins. In some embodiments, the pins 204 share one or more pin features (here, a teardrop style) but differ in one or more pin features (here, various diameters, heights, centerline-to-centerline pitch, and relative degrees of rotation).

In some embodiments, the “teardrop” style pins 204 include a rounded end (also referred to as a base), a pointed end (also referred to as a tip and/or apex), and a curve (also referred to as an arc) that connects the pointed end to the round end. The curve may be symmetrical or asymmetrical, depending on the needs (effect on temperature and/or pressure drop) of the specific teardrop shape. In some embodiments, the teardrop pin style allows for a gradual increase in surface area that can be precisely tuned, for each of the pins 204, by modifying the respective curves between the rounded end and the pointed end. Without wishing to be bound by theory, a teardrop style pin design has been found to be effective at reducing air resistance and pressure drop as well as increasing the overall heat dissipation performance of the heat sink 112 due, in part, to the resultant smooth, streamlined flow of fluid achievable using such designs.

In some embodiments, a first pin 208 of the pins 204 has a first set of pin features (as shown, a teardrop style pin of relatively large diameter and height and having a relatively wide curve). In some embodiments, a second pin 210 of the pins 204 has a second set of pin features (as shown, a teardrop style pin of relatively small diameter and height and having a relatively narrow curve). In some embodiments, a third pin 402 of the pins 204 has a third set of pin features (as shown, a teardrop style pin of moderate diameter, a relatively low height, and having a relatively narrow curve). In some embodiments, a fourth pin 404 of the pins 204 has a fourth set of pin features (as shown, a teardrop style pin of a smallest diameter, a moderate height, and a moderate curve). In some embodiments, the relative degree of rotation (i.e., the relative position of the respective tip of a respective pin) can vary among the pins 204. In some embodiments, the first pin 208, the second pin 210, the third pin 402, and fourth pin 404 can have a same, or different relative degree of rotation, depending on the needs of a particular application (as shown, the first pin 208 and the fourth pin 404 have a same degree of rotation, while the second pin 210 and the third pin 402 each have a unique degree of rotation).

FIG. 5B illustrates a top-down view of the heat sink 112 of FIG. 5A in accordance with one or more embodiments. As shown in FIG. 5B, the heat sink 112 can include plurality of pins 204, such as, for example, the first pin 208 having a first set of pin features (as shown, a teardrop style pin of relatively large diameter and height and having a relatively wide curve), the second pin 210 having a second set of pin features (as shown, a teardrop style pin of moderate diameter, a relatively low height, and having a relatively narrow curve), the third pin 402 having a third set of pin features (as shown, a cylindrical style pin of moderate diameter), and fourth pin 404 having a fourth set of pin features (as shown, a teardrop style pin of a smallest diameter, a moderate height, and a moderate curve).

FIG. 6 illustrates a view of a heat sink 112 in accordance with one or more embodiments. As shown in FIG. 6, the heat sink 112 can include plurality of pins 204. In some embodiments, the pins 204 are variable pins. In some embodiments, the pins 204 are distributed among two or more regions 602 of the heat sink 112 (here, regions 602a, 602b, 602c, 602d, 602e, 602f, 602g, 602h, 602i, and 602j). In some embodiments, one or more of the regions 602 are continuous (e.g., the regions 602b, 602c, 602f, 602h, 602j). In some embodiments, one or more of the regions 602 are discontinuous (e.g., the regions 602a, 602c, 602e, 602g, 602i). In some embodiments, all regions 602 can occupy a same footprint (e.g., surface area) of the heat sink 112. In some embodiments, one or more of the regions 602 can occupy a different (greater or lower) footprint than one or more other regions 602 of the heat sink 112.

In some embodiments, pins 204 in a same region 602 have the same pin features. In some embodiments, pins 204 in different regions 602 will have at least one different pin feature (i.e., some pin features can be unique to a respective region 602 while other pin features can be shared between two or more regions 602). In some embodiments, pins 204 in different regions 602 will have no same pin features (i.e., all pin features can be unique to a respective region 602). In some embodiments, one or more of the regions 602 will have unique pin features (i.e., all pin features can be unique to the respective region 602) while two or more other regions 602 can share one or more pin features. For example, in some embodiments, pins 204 in region 602b can be cylinder style pins having a first height, while pins 204 in region 602d can be cylinder style pins having a second height greater than the first height. Note that the regions 602 depicted in FIG. 6 are shown having a same pin style (e.g., cylindrical) for ease of illustration only. It should be understood that the pin styles themselves can vary among the regions 602 as described previously herein and all such arrangements are within the contemplated scope of this disclosure.

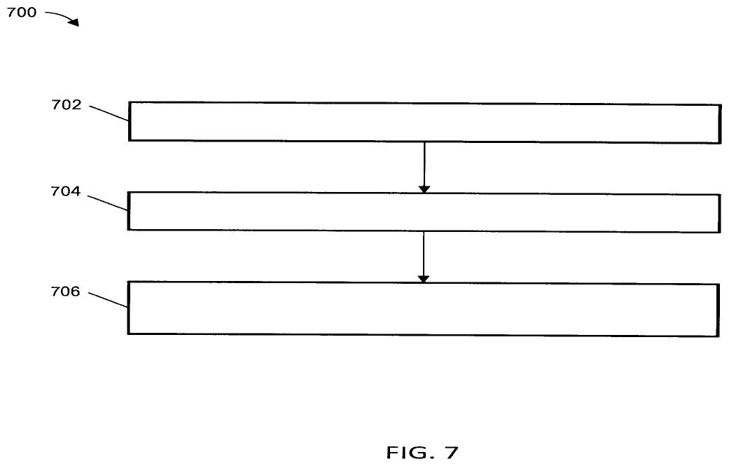

Referring now to FIG. 7, a flowchart 700 for cooling a component of a vehicle using a heat sink having variable pins is generally shown according to an embodiment. The flowchart 700 is described in reference to FIGS. 1 to 6 and may include additional steps not depicted in FIG. 7. Although depicted in a particular order, the blocks depicted in FIG. 7 can be rearranged, subdivided, and/or combined.

At block 702, a heat sink is thermally coupled to the component. The heat sink includes a plurality of pins extending from a surface of the heat sink. In some embodiments, the component is one of an electric motor, a battery pack, and an inverter electrically coupled to the electric motor.

At block 704, a first pin of the plurality of pins is configured with a first set of pin features. At block 706, a second pin of the plurality of pins is configured with a second set of pin features such that the first set of pin features and the second set of pin features differ in at least one pin feature.

In some embodiments, a pin feature includes one of a shape, a height, a diameter, a spacing, a degree of taper, a degree of rotation, a surface area, a volume, and a geometry of a respective pin of the plurality of pins.

In some embodiments, the method further includes providing a cooling system having an inlet and an outlet. In some embodiments, the heat sink is positioned on the component and the heat sink and the component are positioned between the inlet and the outlet of the cooling system.

In some embodiments, a plurality of first pins and a plurality of second pins are configured. In some embodiments, the plurality of first pins and the plurality of second pins are distributed nonuniformly over the surface of the heat sink. In some embodiments, the plurality of first pins are co-located in a first region of the heat sink and the plurality of second pins are co-located in a second region of the heat sink. In some embodiments, at least one of the first region and the second region is discontinuous.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A vehicle comprising:
an electric motor configured to drive at least one wheel of the vehicle;
a battery pack electrically coupled to the electric motor; and
a heat sink thermally coupled to a component of the vehicle, the heat sink comprising:
a plurality of pins extending from one or more surfaces of the heat sink, the plurality of pins comprising one or more first pins and one or more second pins;
the one or more first pins comprising a first set of pin features; and
the one or more second pins comprising a second set of pin features;
wherein the first set of pin features of the one or more first pins and the second set of pin features of the one or more second pins differ in at least one pin feature.

2. The vehicle of claim 1, wherein each pin feature comprises one of a shape, a height, a diameter, a spacing, a degree of taper, a degree of rotation, a surface area, a volume, and a geometry of a respective pin of the plurality of pins.

3. The vehicle of claim 1, wherein the component comprises one of the electric motor, the battery pack, and an inverter electrically coupled to the electric motor.

4. The vehicle of claim 3, further comprising a cooling system having an inlet and an outlet, wherein the heat sink is positioned on the component and wherein the heat sink and the component are positioned between the inlet and the outlet of the cooling system.

5. The vehicle of claim 1, further comprising a plurality of first pins and a plurality of second pins, the plurality of first pins and the plurality of second pins distributed nonuniformly over the one or more surfaces of the heat sink.

6. The vehicle of claim 1, further comprising a plurality of first pins and a plurality of second pins, wherein the plurality of first pins are co-located in a first region of the heat sink and the plurality of second pins are co-located in a second region of the heat sink.

7. The vehicle of claim 6, wherein at least one of the first region and the second region of the heat sink is discontinuous.

8. A heat sink comprising:
a plurality of pins extending from a surface of the heat sink, the plurality of pins comprising a first pin and a second pin;
the first pin comprising a first set of pin features; and
the second pin comprising a second set of pin features;
wherein the first set of pin features and the second set of pin features differ in at least one pin feature.

9. The heat sink of claim 8, wherein a pin feature comprises one of a shape, a height, a diameter, a spacing, a degree of taper, a degree of rotation, a surface area, a volume, and a geometry of a respective pin of the plurality of pins.

10. The heat sink of claim 8, wherein the heat sink is thermally coupled to a component comprising one of an electric motor, a battery pack, and an inverter electrically coupled to the electric motor.

11. The heat sink of claim 10, further comprising a cooling system having an inlet and an outlet, wherein the heat sink is positioned on the component and wherein the heat sink and the component are positioned between the inlet and the outlet of the cooling system.

12. The heat sink of claim 8, further comprising a plurality of first pins and a plurality of second pins, the plurality of first pins and the plurality of second pins distributed nonuniformly over the surface of the heat sink.

13. The heat sink of claim 8, further comprising a plurality of first pins and a plurality of second pins, wherein the plurality of first pins are co-located in a first region of the heat sink and the plurality of second pins are co-located in a second region of the heat sink.

14. The heat sink of claim 13, wherein at least one of the first region and the second region of the heat sink is discontinuous.

15. A method for cooling a component of a vehicle, the method comprising:
thermally coupling a heat sink to the component, the heat sink comprising a plurality of pins extending from a surface of the heat sink;
configuring a first pin of the plurality of pins with a first set of pin features; and
configuring a second pin of the plurality of pins with a second set of pin features;
wherein the first set of pin features and the second set of pin features differ in at least one pin feature.

16. The method of claim 15, wherein a pin feature comprises one of a shape, a height, a diameter, a spacing, a degree of taper, a degree of rotation, a surface area, a volume, and a geometry of a respective pin of the plurality of pins.

17. The method of claim 15, wherein the component comprises one of an electric motor, a battery pack, and an inverter electrically coupled to the electric motor.

18. The method of claim 17, further comprising providing a cooling system having an inlet and an outlet, wherein the heat sink is positioned on the component and wherein the heat sink and the component are positioned between the inlet and the outlet of the cooling system.

19. The method of claim 15, further comprising configuring a plurality of first pins and configuring a plurality of second pins, the plurality of first pins and the plurality of second pins distributed nonuniformly over the surface of the heat sink.

20. The method of claim 15, further comprising configuring a plurality of first pins and configuring a plurality of second pins, wherein the plurality of first pins are co-located in a first region of the heat sink and the plurality of second pins are co-located in a second region of the heat sink.
